(19) United States
(12) Patent Application Publication
(10) Pub. No.: US 2014/0029326 A1
(43) Pub. Date: Jan. 30, 2014

(54) FERROELECTRIC RANDOM ACCESS MEMORY WITH A NON-DESTRUCTIVE READ

(71) Applicant: Saim A. Qidwai, Allen, TX (US)

(72) Inventor: Saim A. Qidwai, Allen, TX (US)

(73) Assignee: TEXAS INSTRUMENTS INCORPORATED, Dallas, TX (US)

(21) Appl. No.: 13/559,001

(22) Filed: Jul. 26, 2012

(51) Int. Cl. G11C 11/22

(52) U.S. Cl. 365/145

(57) ABSTRACT

An embodiment of the invention provides a ferroelectric random access memory with a non-destructive read cycle. During the non-destructive read cycle, a plate of the ferroelectric capacitor in a selected one-capacitor, one-transistor memory cell and a bit line electrically connected to the selected one-capacitor, one-transistor memory cell are grounded. A word line electrically connected to a pass transistor in the one-capacitor, one-transistor selected memory cell is charged to a logical high value. The pass-transistor connects the bit line and the ferroelectric capacitor. The bit line is charged to a voltage less than the disturb voltage of the ferroelectric capacitor. The sense amplifier senses the voltage difference between the voltage on the bit line and a reference voltage. After the sensing occurs, the word line is grounded.

### BACKGROUND

Many modern electronic devices and systems now include substantial computational capability for controlling and managing a wide range of functions and useful applications. Many of these electronic devices and systems are now portable or handheld devices. For example, many mobile devices with significant computational capability are now available in the market, including modern mobile telephone handsets such as those commonly referred to as “smart phones”, personal digital assistants (PDAs), mobile Internet devices, tablet-based personal computers, handheld scanners and data collectors, personal navigation devices, implantable medical devices, and the like.

A recently developed technology for realizing non-volatile solid-state memory devices involves the construction of capacitors in which the dielectric material is a polarizable ferroelectric material, such as lead zirconate titanate (PZT) or strontium-bismuth-tantalate (SBT). Hysteresis in the charge-vs.-voltage (Q-V) characteristic, based on the polarization state of the ferroelectric material, enables the non-volatile storage of binary states in those capacitors. In contrast, conventional MOS capacitors lose their stored charge on power-down of the device. It has been observed that ferroelectric capacitors can be constructed by processes that are largely compatible with modern CMOS integrated circuits, for example by forming the capacitors above the transistor level, between overlying levels of metal conductors.

Ferroelectric technology is now utilized in non-volatile solid-state read/write memory devices. These memory devices, commonly referred to as “ferroelectric RAM”, or “FeRAM”, or “FRAM” devices, now appear in many electronic systems, particularly portable electronic devices and systems. FRAM memories are especially attractive in implantable medical devices, such as pacemakers and defibrillators.

As known in the art, FRAM cells may be implemented in various forms, including as a one-transistor, one-capacitor (1-T, 1-C) memory cell similar to a typical DRAM cell. Other implementations include a two-transistor, two-capacitor (2-T, 2-C) cells, in which the two capacitors differentially define the stored data state, and six-transistor (6-T) SRAM cells that include one or two ferroelectric capacitors that are programmed to retain the SRAM data state after power is removed.

FIG. 1a illustrates the construction of a conventional 1-T, 1-C FRAM memory cell 4, as is now typically used in modern FRAMs. Ferroelectric capacitor 5 serves as the non-volatile memory element, and is constructed as a parallel-plate solid-state capacitor with ferroelectric dielectric material, such as PZT, as the capacitor dielectric. In this example, FRAM cell 4 resides in row j and column k of an array of similarly constructed FRAM cells 4. One plate of capacitor 5 is connected to plate line PLⱼ for the j^{th} row of the array, and the other plate of capacitor 5 is connected to one end of the source/drain path of n-channel metal-oxide-semiconductor (MOS) transistor 6. The other end of the source/drain path of transistor 6 is connected to bit line BLₖ for the k^{th} column of the array, and the gate of transistor 6 is connected to word line WLⱼ of the j^{th} row of the array. As such, transistor 6 serves as a pass transistor in the DRAM sense, connecting ferroelectric capacitor 5 to bit line BLₖ upon selection of row j according to a row address that indicates energizing of word line WLⱼ.

As mentioned above, the data storage mechanism of FRAM cells is the charge-voltage hysteresis of the ferroelectric capacitor dielectric. FIG. 1b illustrates an example of a Q-V characteristic of a conventional ferroelectric capacitor, such as capacitor 5 in cell 4 of FIG. 1a. As shown, the charge (Q) stored across the conductive plates depends on the voltage applied to the plates (V), and also on the recent history of that voltage. If the voltage V applied across the capacitor plates exceeds a “coercive” voltage +V_{α} the capacitor polarizes into the “+1” state. According to this characteristic, once polarized to the “+1” state, so long as voltage V remains above coercive voltage −V_{β}, the capacitor exhibits a stored charge of +Q₁. Conversely, if an applied voltage V is more negative than coercive voltage −V_{β}, the capacitor is polarized into the “−1” state, and will exhibit a stored charge of −Q₂. The disturb voltage V_{disturb} is a voltage applied to the ferroelectric capacitor that reduces the current polarization but does change the current logical data state (e.g. changing from the “+1” state to the “−1” state or from the “−1” state to the “+1” state).

An important characteristic of ferroelectric capacitors, for purposes of non-volatile storage in integrated circuits, is the difference in capacitance exhibited by a ferroelectric capacitor its two polarized states. As fundamental in the art, the capacitance of an element refers to the ratio of stored charge to applied voltage. In the context of a ferroelectric capacitor, the change in polarization state that occurs upon application of a polarizing voltage is reflected by the amount of charge stored by the capacitor as a result. As shown in FIG. 1b, the polarization of ferroelectric capacitor 5 from its “−1” state to its “+1” state is reflected by a relatively high capacitance C(−1), reflecting significant polarization charge that is stored as a result of the change of polarization state as the voltage exceeds its coercive voltage V_{α}. On the other hand, if capacitor 5 is already in its “+1” state, little polarization charge is stored as a result of the application of that voltage, and thus the capacitance C(+1) is relatively small, since the ferroelectric domains of capacitor 5 are already aligned prior to the application of the voltage. As such, the stored data state in FRAM cell 4 can be read by interrogating the capacitance of ferroelectric capacitors to discern its previous polarized state.

FIG. 2 is a timing diagram illustrating the reading and writing of FRAM cell 4 of FIG. 1a, in a conventional FRAM. As well-known in the art, sensing of the state of 1-T, 1-C memory cells (such as in DRAMs and FRAMs) is carried out by a differential MOS sense amplifier connected on one side to a bit line BLₖ and on another side to a reference voltage that is set approximately half-way between the “0” and “1” data states (e.g., as established by a “dummy” cell). The cycle shown in FIG. 2 begins with the precharge of bit line BLₖ to a ground voltage (near 0 volts in this example), with both word line WLⱼ and plate line PLⱼ also near ground. Word line WLⱼ is then energized to a high voltage (e.g., at or near power supply voltage V_{dd}), upon a received memory address indicating row j for access. In this conventional operation, a three-pulse operation is performed within each pulse of word line WLⱼ. The first pulse in this sequence is a “read” of cell 4 in row j and each column k (one of which is shown in FIG. 2), initiated by plate line PLⱼ being driven to a high voltage.

In this “read” pulse, referring back to FIGS. 1a and 1b, plate line PLⱼ is driven to a high voltage during the word line pulse, with bit line BLₖ having been pre-charged to ground. Considering the voltage V of the Q-V curve of FIG. 1b as corresponding to the voltage differential between plate line PLⱼ and bit line BLₖ VPL−VBL), this pulse of plate line PLⱼ amounts to raising of the voltage V above 0 volts, toward “coercive” voltage +V_{α} If capacitor 5 is in its “−1” polarization state, this plate line pulse will cause capacitor 5 to exhibit capacitance C(−1), transferring charge to bit line BLₖ; conversely, if capacitor 5 is in its “+1” state, the plate line pulse will follow capacitance C(+1), transferring much less charge to bit line BLₖ. This charge transfer develops a voltage response at bit line BLₖ as shown in FIG. 2 by plots BLₖ(D1) for the “1” data state (resulting from the “−1” polarization state) and BLₖ(D0) for the “0” data state (resulting from the “+1” polarization state).

In most modern FRAMs of this construction, plate line PLⱼ is then de-energized after the charge transfer to bit line BLₖ, after which the differential sense amplifier senses the transferred charge (by determining the polarity of the differential voltage between bit line BLₖ and a reference level), and develops its full differential data state as a result. This “off-pulse” sensing has been observed to provide better read margin than “on-pulse” sensing (i.e., flipping of the sense amplifier during the plate line pulse.

In either data state, the read of FRAM cell 4 in this manner is destructive, in that capacitor 5 is at least partially polarized by this operation. Conventional FRAM operation thus restores the sensed data state. In the conventional approach of FIG. 2, the “0” data state is written to every FRAM cell 4 in row j, by again pulsing plate line PLₖ to a high voltage while holding bit line BLₖ (and all bit lines corresponding to cells 4 in the selected row j) at ground. This pulse writes a “0” to each of these cells 4, by applying a full voltage beyond coercive voltage +V_{α} across each ferroelectric capacitor 5. Following this unconditional “0” write pulse, a “1” data state is then written into those FRAM cells 4 in this row j that previously stored a “1” data state. This write “1” pulse consists of holding plate line PLⱼ low for row j, while driving bit lines BLₖ corresponding to those “1” data state cells 4 to a high voltage. This operation applies a negative voltage beyond coercive voltage −V_{β} (FIG. 1b) across the corresponding capacitors 5, polarization those capacitors into the “−1” state. Of course, the selection of which bit lines BLₖ receive this “1” write pulse can be modified from that indicated by the sensed data states, for example in a read-modify-write operation or as a result of error correction.

This conventional FRAM memory operation has been observed to provide reasonably good data stability and performance. However, as evident from FIG. 2, the necessity to perform the multiple pulses and intervals within each read cycle (“read”, “sense”, “write 0”, “write 1”) limits memory performance by requiring relatively long cycle times.

### BRIEF DESCRIPTION OF THE SEVERAL VIEWS OF THE DRAWING

FIG. 1a is a schematic diagram of a conventional one-transistor, one-capacitor (1-T, 1-C) ferroelectric memory cell. (Prior Art)

FIG. 1b is a plot of the charge-voltage polarization characteristic of a typical conventional ferroelectric capacitor. (Prior Art)

FIG. 2 is a timing diagram illustrating the operation of a conventional ferroelectric random access memory (FRAM) in performing a read cycle. (Prior Art)

FIG. 3 is an electrical diagram, in block form, of a large scale integrated circuit incorporating a ferroelectric memory, constructed according to embodiments of the invention.

FIG. 4 is an electrical diagram, in block form, of a ferroelectric memory constructed according to embodiments of the invention.

FIG. 5 is an electrical schematic of a column of two-transistor, two-capacitor (2-T, 2-C) ferroelectric memory cells connected to a sense amp, a constant current source and a pre-charge circuit according to an embodiment of the invention.

FIG. 6 is a schematic diagram of a current mirror. (Prior Art)

FIG. 7 is a schematic diagram of a sense amplifier according to an embodiment of the invention.

FIG. 8 is a block diagram of a timing generation circuit according to an embodiment of the invention.

FIG. 9 is timing diagram illustrating the timing of the signals generated by the timing generation circuit according to an embodiment of the invention

FIG. 10 is a timing diagram illustrating how a two-transistor, two-capacitor (2-T, 2-C) ferroelectric memory cell is read according to an embodiment of the invention.

FIG. 11 is a block diagram of a column of one-transistor, one-capacitor (1-T, 1-C) ferroelectric memory cells connected to a sense amp, a constant current source and a pre-charge circuit according to an embodiment of the invention.

FIG. 12 is a schematic of a current mirror. (Prior Art)

FIG. 13 is a of a sense amplifier according to an embodiment of the invention.

FIG. 14 is a timing diagram illustrating how a one-transistor, one-capacitor (1-T, 1-C) ferroelectric memory cell is read according to an embodiment of the invention.

FIG. 15 is a flow chart illustrating how a two-transistor, two-capacitor (2-T, 2-C) ferroelectric memory cell is read according to an embodiment of the invention.

FIG. 16 is a schematic drawing of a pre-charge circuit. (Prior Art)

FIG. 17 is a schematic drawing of a pre-charge circuit. (Prior Art)

### DETAILED DESCRIPTION OF THE INVENTION

This invention will be described in connection with certain of its embodiments, namely as implemented into ferroelectric random access memory (FRAM or FeRAM) in which the memory cells are constructed in the well-known 1-T, 1-C arrangement or the well-known two-transistor, two-capacitor (2-T, 2-C) arrangement, because it is contemplated that this invention is especially beneficial when applied to such circuits. However, it is also contemplated that other memory circuits and architectures, including FRAM cells of different construction, may also greatly benefit from this invention. Accordingly, it is to be understood that the following description is provided by way of example only, and is not intended to limit the true scope of this invention as claimed.

As mentioned above, this invention is suitable for use in connection with semiconductor memory circuits, whether serving as a stand-alone integrated circuit or as embedded into larger scale integrated circuits such as microprocessors, microcontrollers, or the so-called “system on a chip” (SoC) integrated circuits. This invention is also suitable for use in logic circuits, including combinational and sequential logic circuits, as well as programmable logic circuits. Examples of embodiments of this invention in memory and logic circuits will be described in this specification, it being understood that such descriptions of implementations of this invention are not to be interpreted in a limiting fashion.

FIG. 3 illustrates an example of SoC large-scale integrated circuit 10, which is a single-chip integrated circuit into which entire computer architecture is realized. As such, in this example, integrated circuit 10 includes a central processing unit of microprocessor 12, which is connected to system bus SBUS. Various memory resources, including ferroelectric random access memory (FRAM) 18 and read-only memory (ROM) 19, reside on system bus SBUS and are thus accessible to microprocessor 12. Typically, ROM 19 serves as program memory, storing the program instructions executable by microprocessor 12, while FRAM 18 serves as data memory; in some cases, program instructions may reside in FRAM 18 for recall and execution by microprocessor 12. Cache memory 16 (such as level 1, level 2, and level 3 caches, each typically implemented as static RAM) provides another memory resource, and resides within microprocessor 12 itself and therefore does not require bus access. Other system functions are shown, in a generic sense, in integrated circuit 10 by way of system control 14 and input/output interface 17.

Those skilled in the art having reference to this specification will recognize that integrated circuit 10 may include additional or alternative functions to those shown in FIG. 3, or may have its functions arranged according to a different architecture from that shown in FIG. 3. The architecture and functionality of integrated circuit 10 is thus provided only by way of example, and is not intended to limit the scope of this invention.

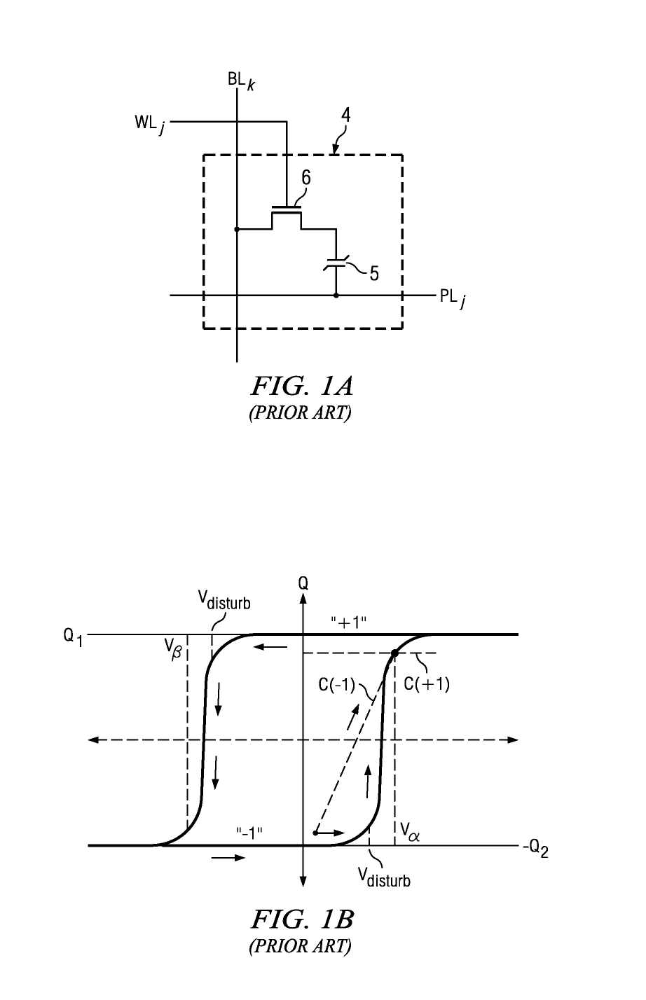

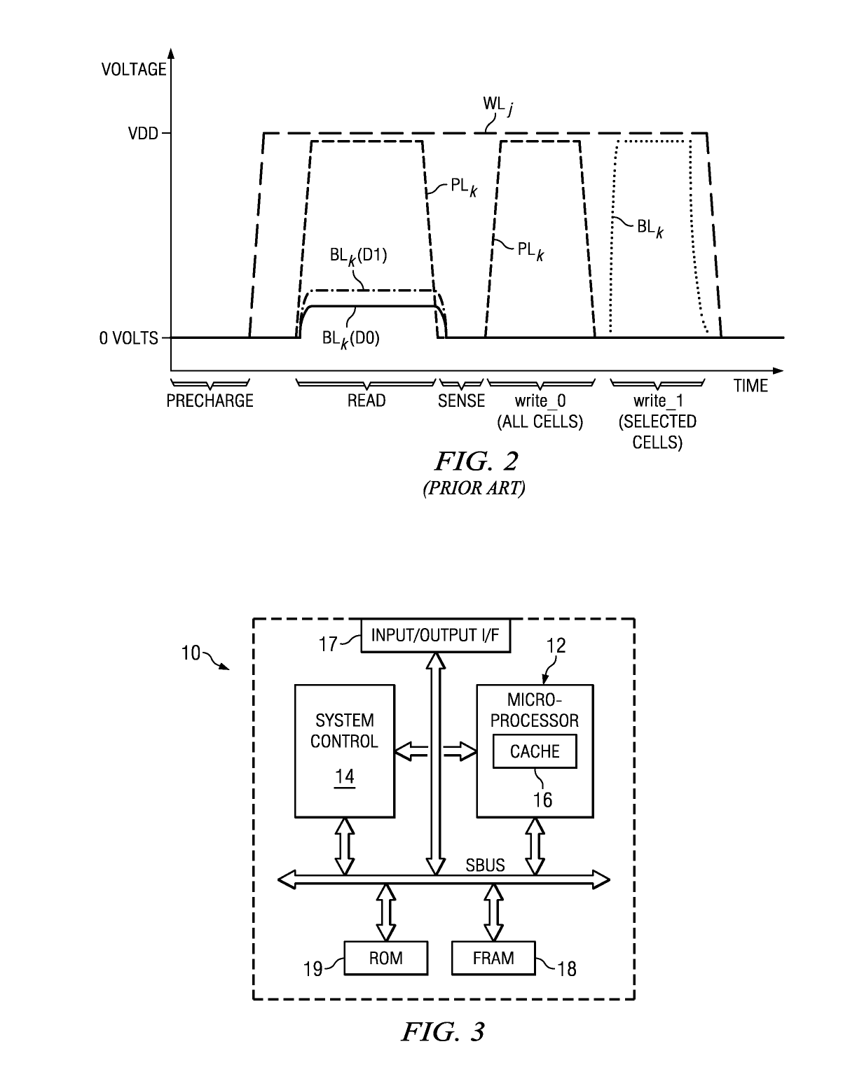

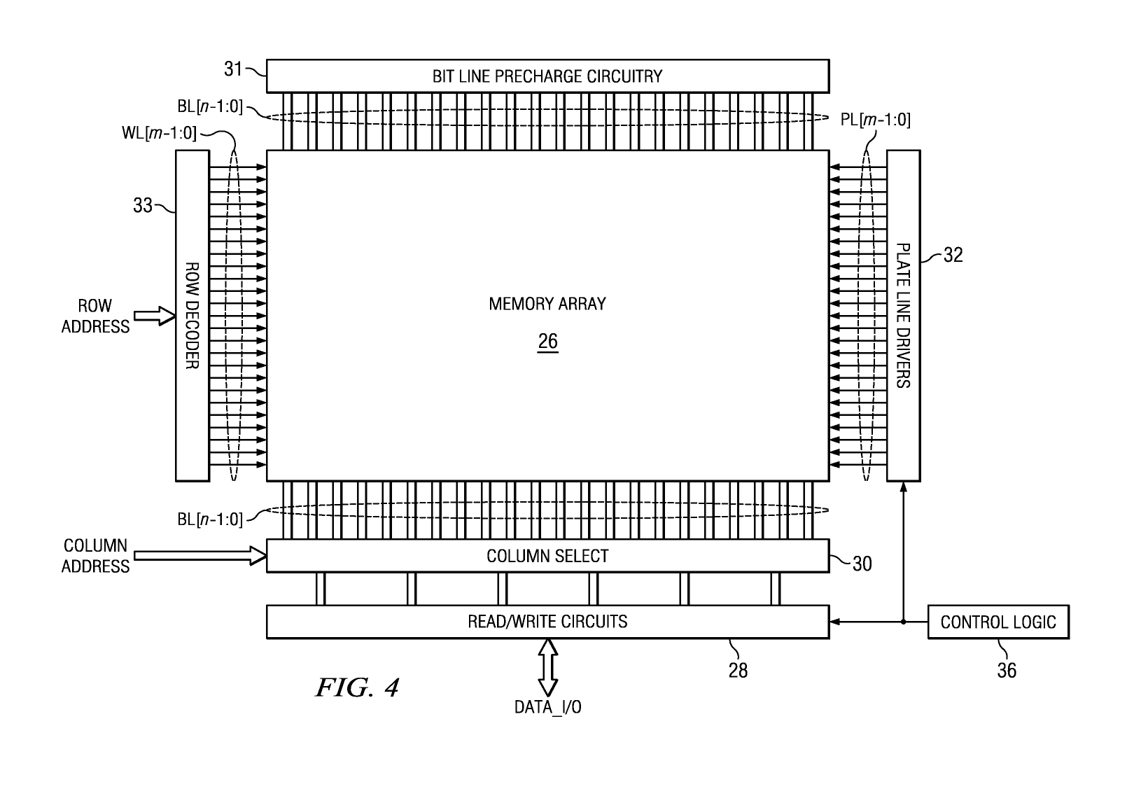

FIG. 4 shows an example of the architecture of FRAM 18 implementing an embodiment of this invention. Memory array 26 includes non-volatile FRAM memory cells of the 1-T, 1-C construction described above relative to FIG. 1a, arranged in m rows and n columns. FRAM memory cells in the same column share a pair of bit lines BL[n-1:0], and memory cells in the same row share one of word lines WL[m-1:0]. Row decoder 33 receives a row address value indicating the row of memory array block 26 to be accessed, and includes word line drivers that energize the one of word lines WL[m-1:0] corresponding to that row address value. Column select circuit 30 receives a column address value, and in response selects one or more pairs of bit lines BL[n-1:0] for connection to read/write circuits 28, which may be realized as conventional sense amplifiers and write circuits as known in the art for FRAM devices. Read/write circuits 28 are coupled to bus DATA_I/O, by way of which output data and input data are communicated from and to read/write circuits 28 and thus the addressed memory cells within memory array 26, in the conventional manner. Bit line pre-charge circuitry 31 is provided to apply a desired voltage to the pairs of bit lines BL[n-1:0] at the beginning of read and write operations, and during standby periods.

Of course, many variations in the particular memory arrangement can be realized within this architecture, and by way of variations to this architecture, in connection with this embodiment of the invention. For example, each FRAM cell may alternatively be constructed of the 2-T/2-C type, with one ferroelectric capacitor and pass transistor in each cell coupled to one bit line and the other capacitor and transistor combination coupled to a complementary bit line. Each of the two transistors receives the same word line level in each cycle, and also the same plate line voltage from plate line drivers 32 (described below). In write operations, the complementary bit lines in each column carry complementary data levels to polarize the two ferroelectric capacitors within each cell to opposite states, differentially defining the stored data state. Other cell constructions and memory architectures may alternatively realize FRAM 18 according to embodiments of this invention, without departing from this invention as hereinafter claimed.

As described above, the memory cells within memory array 26 have non-volatile capability provided by ferroelectric capacitors that can be polarized to retain the current state of corresponding memory cells. In this regard, the memory of FIG. 4 also includes plate line drivers 32, which drive plate line conductors PL[m-1:0] that are connected to ferroelectric capacitors in memory cells of memory array 26, in the manner described above relative to FIG. 1a. Typically, these plate lines PL[m-1:0] are dedicated to groups of one or more rows, in similar manner as word lines WL[m-1:0], and thus are selectively energized based on the row address decoded by row decoder 33. Plate line drivers 32, as well as read/write circuits 28 and other circuitry within the memory, are also controlled by control logic 36, which refers generally to logic circuitry that controls the operation of plate line drivers 32, bit line pre-charge circuitry 31, and read/write circuits 28, in response to clock signals and control signals (not shown).

Control logic 36 in FRAM 18 according to embodiments of this invention may be constructed in the usual manner for modern FRAMs, generally distributed around and among the various functions shown in FIG. 4; the illustration of a single control logic block in FIG. 4 is presented for clarity of the drawing. It is contemplated that those skilled in the art having reference to this specification, and particularly to the description of the various control signals and timing of those control signals for embodiments of this invention, will be readily able to construct and realize control logic 36 in an appropriate way for each particular implementation, without undue experimentation. It is therefore contemplated that the description of the various control signals and timing in the operation of FRAM 18 in this specification will be sufficient for such construction, without requiring detailed description of any particular logic realization for control logic 36. As such, no such detailed construction for control logic 36 will be presented, for the sake of clarity.

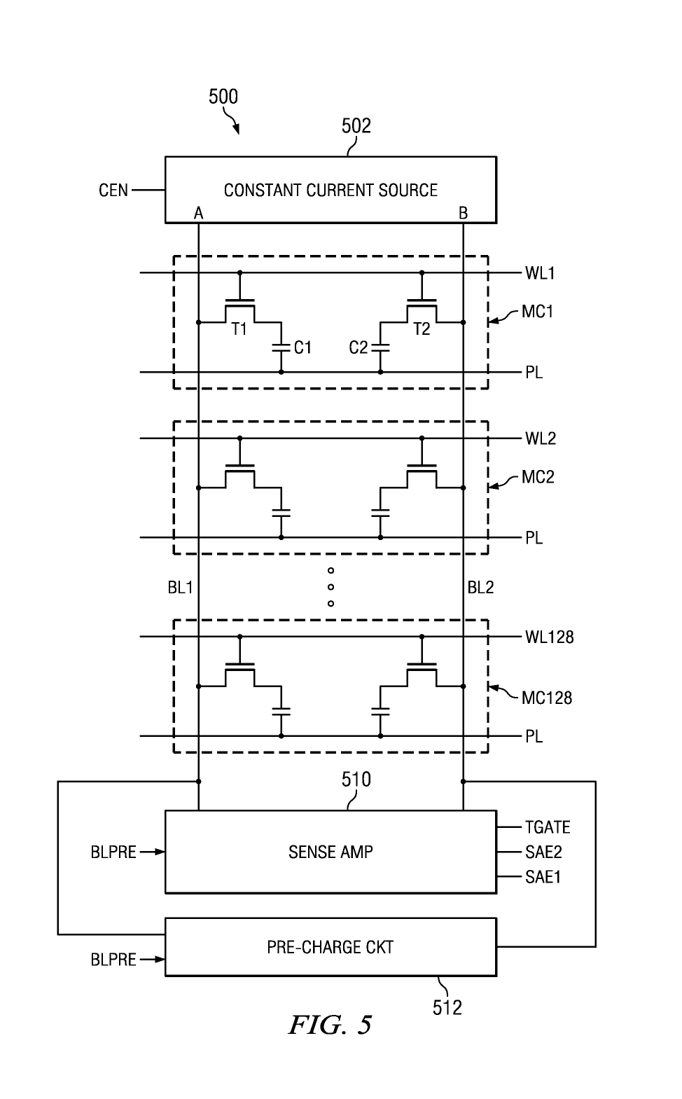

FIG. 5 is a block diagram of a column of two-transistor, two-capacitor (2-T, 2-C) ferroelectric memory cells MC1-MC128 connected to a sense amp 510, a constant current source 502 and pre-charge circuit 512 according to an embodiment of the invention. Write circuitry is not shown in this example to illustrate how a ferroelectric memory cell is read without changing the data state of the ferroelectric memory cell. In FIG. 5, 2-T, 2-C ferroelectric memory cells MC1-MC128 are electrically connected to the sense amp 510, constant current source 502 and the pre-charge circuit 512 through bit lines BL1 and BL2. The ferroelectric memory cell MC1 illustrates how 2-T, 2-C ferroelectric memory cell is constructed. The source of transistor T1 is connected to bit line BL1 while the source of transistor T2 is connected to bit line BL2. The word line WL1 is connected to the gates of transistors T1 and T2. The drain of transistor T1 is connected to a plate of capacitor C1 and the drain of transistor T2 is connected to a plate of capacitor C2. The other plates of capacitors C1 and C2 are connected to the plate line PL.

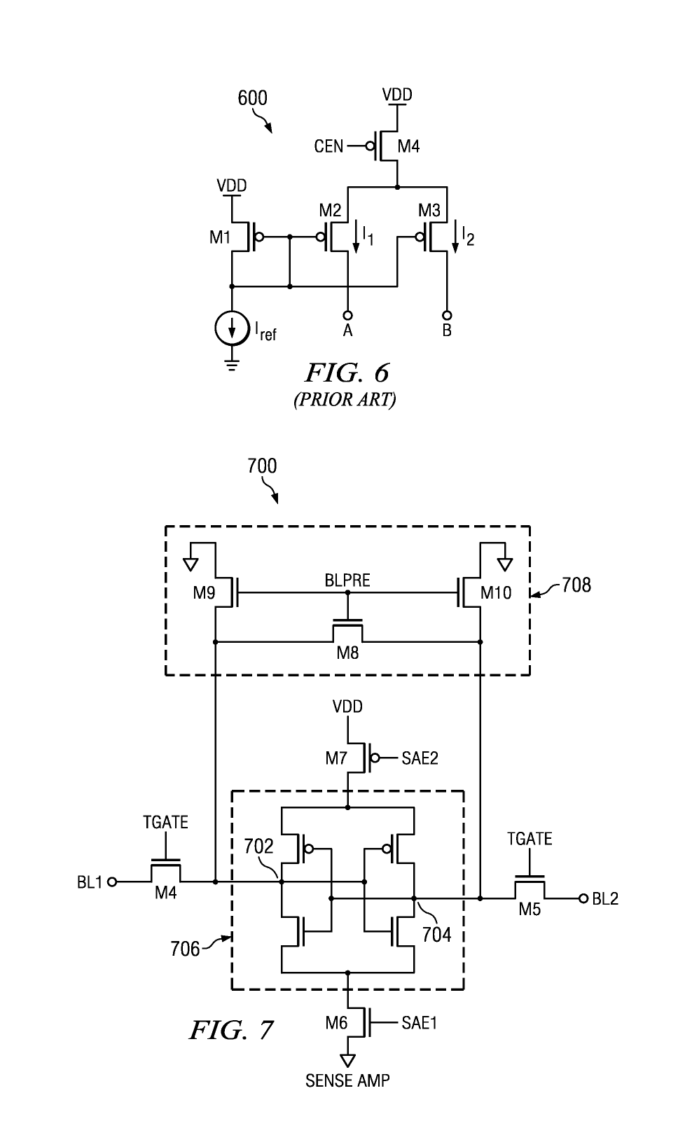

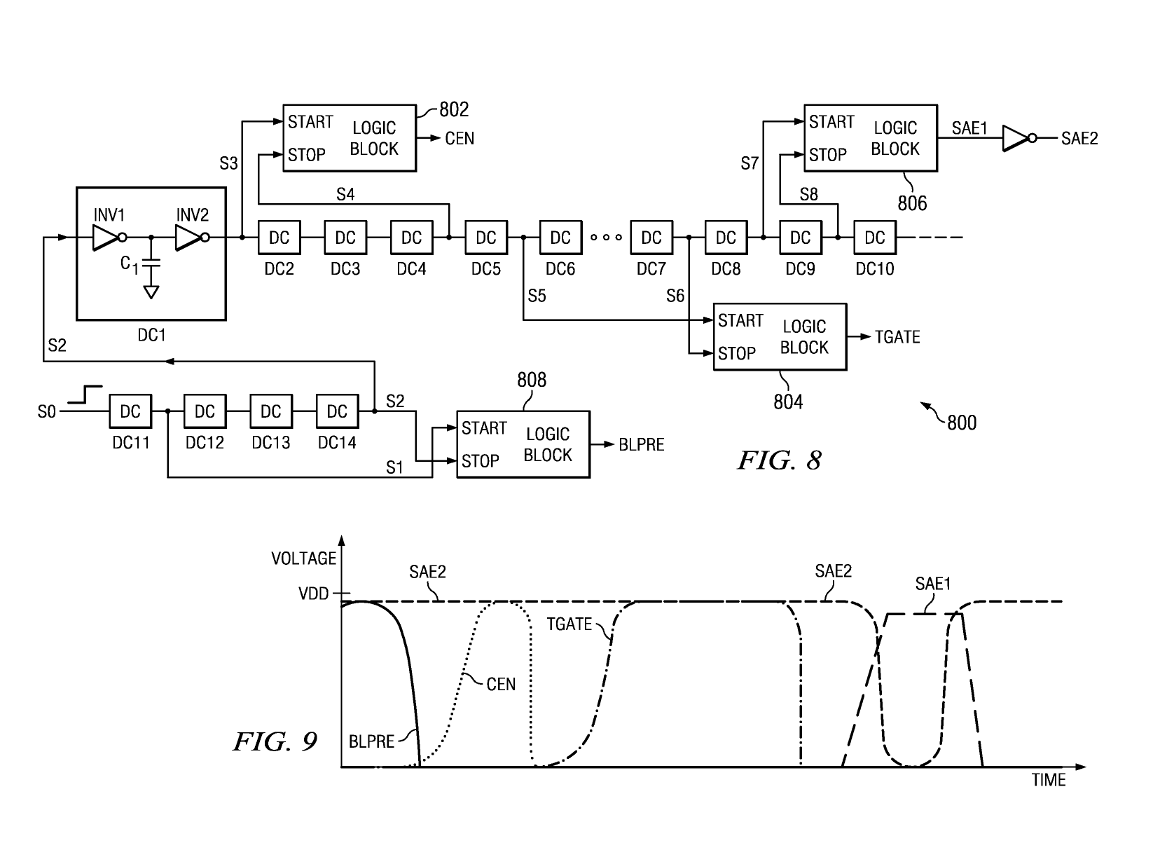

FIG. 6 is a schematic diagram of a current mirror. The current mirror 600 shown in FIG. 6 is an example of a constant current source 502 that may be used to charge bit lines BL1 and BL2 shown in FIG. 5. In this example of a constant current source 502, the current mirror 600 includes four PFET (p-type field-effect transistor) transistors, M1, M2, M3 and M4, and a current reference I_{ref}. When transistor M4 is enabled (i.e. CEN is a high logical value), the constant current in current reference I_{ref} is “mirrored” in transistors M2 and M3. When the transistors M2 and M3 are nearly identical in size (i.e. width and length) and having nearly identical electrical properties (i.e. oxide thickness, mobility etc.), the constant currents I1 and I2 drawn through transistors M2 and M3 are practically identical. The timing of signal CEN is controlled by the timing generation circuit 800 shown in FIG. 8.

FIG. 7 is a schematic diagram of a sense amplifier 510. The schematic 700 shown in FIG. 7 comprises a cross-coupled latch 706, two transfer-gate transistors M4 and M5, transistors M6 and M7 that enable the latch 706 and a pre-charge circuit 708. The pre-charge circuit 708 comprises NMOS transistors M8, M9 and M10 that pre-charge nodes 702 and 704 to ground when control signal BLPRE is a logical high value. The signals that control the operation of the sense amplifier are TGATE (transfer gate), SAE1 (sense amp enable) and SAE2 (sense amp enable). The timing of the control signals TGATE, SAE1, SAE2 and BLPRE are controlled by the timing generation circuit 800 shown in FIG. 8.

FIG. 16 is a schematic diagram of a pre-charge circuit 1600. The schematic 1600 shown in FIG. 16 comprises NMOS transistors M1, M2 and M3 that pre-charge bit lines BL1 and BL1 to ground when control signal BLPRE is a logical high value. The timing of the control signal BLPRE is controlled by the timing generation circuit 800 shown in FIG. 8.

FIG. 8 is a block diagram of a timing generation circuit 800 according to an embodiment of the invention. The timing generation circuit 800 generates the control signals TGATE, SAE1, SAE2, BLPRE and CEN using delay cells DC1-DC14 and logic blocks 802-808. A delay cell as illustrated in delay cell DC1 comprises two inverters INV1 and INV2 and a capacitor C1. The delay is created by the time it takes for a signal to travel through the first inverter INV1, charge or discharge capacitor C1 and travel through inverter INV2.

In this example, a rising edge signal S0 starts the delay chain. After one delay, a rising edge signal S1 is input into logic block 808 and the signal BLPRE is driven to a logical high value as shown in FIG. 9. After three delays, a rising edge signal S2 is input into logic block 808 and the signal BLPRE is driven to a logical low value as shown in FIG. 9. After one delay, a rising edge signal S3 is input into logic block 802 and the signal CEN is driven to a logical high value as shown in FIG. 9. After three delays, a rising edge signal S4 is input into logic block 802 and the signal CEN is driven to a logical low value as shown in FIG. 9.

After one delay, a rising edge S5 is input into logic block 804 and the signal TGATE is driven to a logical high value as shown in FIG. 9. After more delays, S6 is input into logic block 804 and the signal TGATE is driven to a logical low value. After one delay, a rising edge S7 is input into logic block 806 and signal SAC1 is driven to a logical high level and SAC2 is driven from a logical high level to a logical low level. After one delay, a rising edge S8 is input into logic block 806 and signal SAC1 is driven to a logical low level and SAC2 is driven to a logical high level.

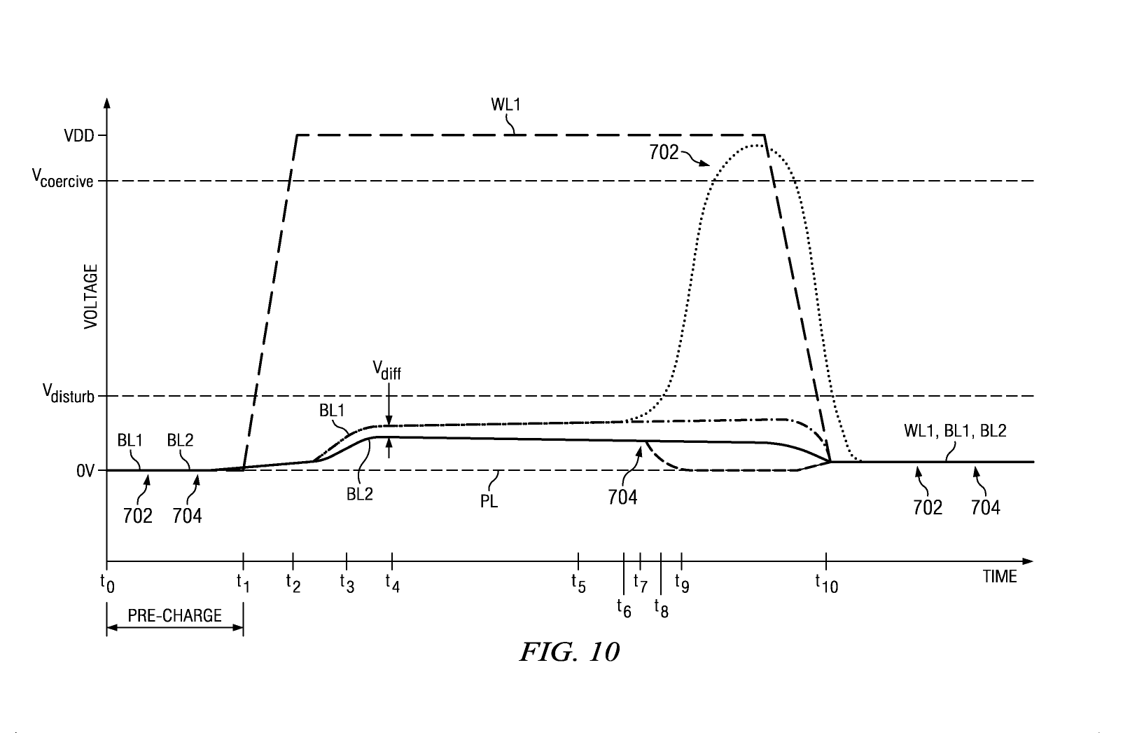

FIG. 10 is a timing diagram illustrating how 2-T, 2-C ferroelectric memory cell is read according to an embodiment of the invention. In this example of the invention, from time t0 to time t1, the bit lines BL1 and BL2 and nodes 702 and 704 of the sense amp 512 are grounded (See FIG. 5). The plate lines PL are ground during the entire reading of the memory cell MC1. At time t2, word line WL1 is driven to a logical high value. In this example the ferroelectric capacitor C1 is charged to a logical one and the ferroelectric capacitor C2 is charged to a logical zero. When the word line WL1 is driven to a logical high value, transistor T1 electrically connects ferroelectric capacitor C1 to bit line BL1 and transistor T2 is electrically connects ferroelectric capacitor C2 to bit line BL2. As result, the total capacitance seen at port A of the constant current source 502 is equal to the capacitance of the bit line BL1 and the ferroelectric capacitor C1 and the total capacitance seen at port B of the constant current source 502 is equal to the capacitance of the bit line BL2 and the ferroelectric capacitor C2.

Because the capacitance of bit lines BL1 and BL2 are essentially equal, the difference in capacitance seen by the constant current source at ports A and B is determined by the capacitance of the ferroelectric capacitors C1 and C2. In this example, C1 has a logical 1 stored on it and C2 has a logical 0 stored on it. In this case, a logical 0 creates more capacitance on ferroelectric capacitor C2 than the capacitance created by a logical 1 on capacitor C1. Because ports A and B provide essentially equal constant current and the capacitance of C1 is smaller than the capacitance of C2, the voltage V_{bl1} on bit line BL1 will increase faster than the voltage V_{bl2}. The charging of bit lines BL1 and BL2 starts at t2 in FIG. 10. At time t3, the constant current source 502 is turned off and the bit lines BL1 and BL2 are no longer charged by the constant current source 502. The time from t2 to t3 is calculated so as to not allow the voltage V_{bl1} on bit line BL1 or the voltage Vbl2 on BL2 to exceed the disturb voltage V_{disturb}. The disturb voltage V_{disturb} is any voltage applied to the ferroelectric capacitors C1 and C2 that reduces the polarization on either ferroelectric capacitor C1 and C2. If polarization is reduced over time (e.g. during consecutive reads) and the stored states on the capacitors are close to being changed, the states stored on ferroelectric capacitors C1 and C2 are refreshed to their original states by writing to them. The coercive voltage V_{coercive} is less than VDD.

From time t4 until time t9, the voltage differential V_{diff} between bit lines BL1 and BL2 is sensed by the sense amp 510. The sensing begins by turning on the transfer-gate transistors M4 and M5 shown in FIG. 7. The signal TGATE is applied to the gates of transistors M4 and M5 at time t4. At time t4, the signal TGATE is a logical high signal and the transfer-gate transistors M4 and M5 are turned on. Because the transfer-gate transistors M4 and M5 are turned on, the voltages (V_{bl1} and V_{bl2}) on bit lines BL1 and BL2 respectively are transferred to nodes 702 and 704 respectively. At time t5, the transfer-gate transistors M4 and M5 are turned off, containing the V_{diff} between nodes 702 and 704.

At time t6, signal SAE1 goes to a logical high value and turns on transistor M6 (See FIG. 7). Turning on transistor M6 connects latch 706 to ground. At time t7, signal SAE2 transitions from a logical high value to a logical low value turning on transistor M7. When transistor M7 is on, the voltage VDD is applied to the latch 706. After both ground and VDD are applied to the latch, the latch 706 “flips” and node 702 is driven to nearly voltage VDD and node 704 is driven to nearly ground. At time t8, the signal SAE1 goes to a logical low level turning off transistor M6. At time t9, the signal SAE2 goes to a logical high level turning off transistor M7 and ending the sensing time of the sense amp. At time t10, the word line WL1, the bit lines BL1 and BL2 and nodes 702 and 704 are grounded.

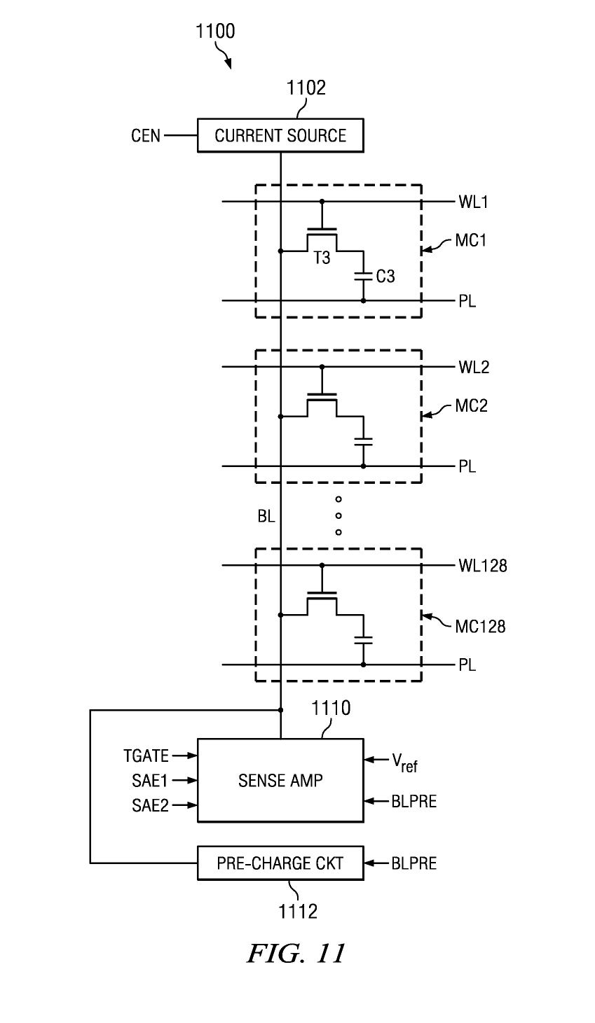

FIG. 11 is a block diagram of a column 1100 of 1-T, 1-C ferroelectric memory cells MC1-MC128 connected to a sense amp, a constant current source and a pre-charge circuit according to an embodiment of the invention. Write circuitry is not shown in this example to help illustrate how a ferroelectric memory cell MC1 is read without changing the content of the ferroelectric memory cell MC1. In FIG. 11, 1-T, 1-C ferroelectric memory cells MC1-MC128 are electrically connected to the sense amp 1110, the current source 1102 and the pre-charge circuit 1112 through bit line BL. The ferroelectric memory cell MC1 illustrates how a 1-T, 1-C ferroelectric memory cell MC1 is constructed. The source of transistor T3 is connected to bit line and the word line WL1 is connected to the gate of transistor T3. The drain of transistor T3 is connected to a plate of capacitor C3. The other plate of capacitor C3 is connected to the plate line PL.

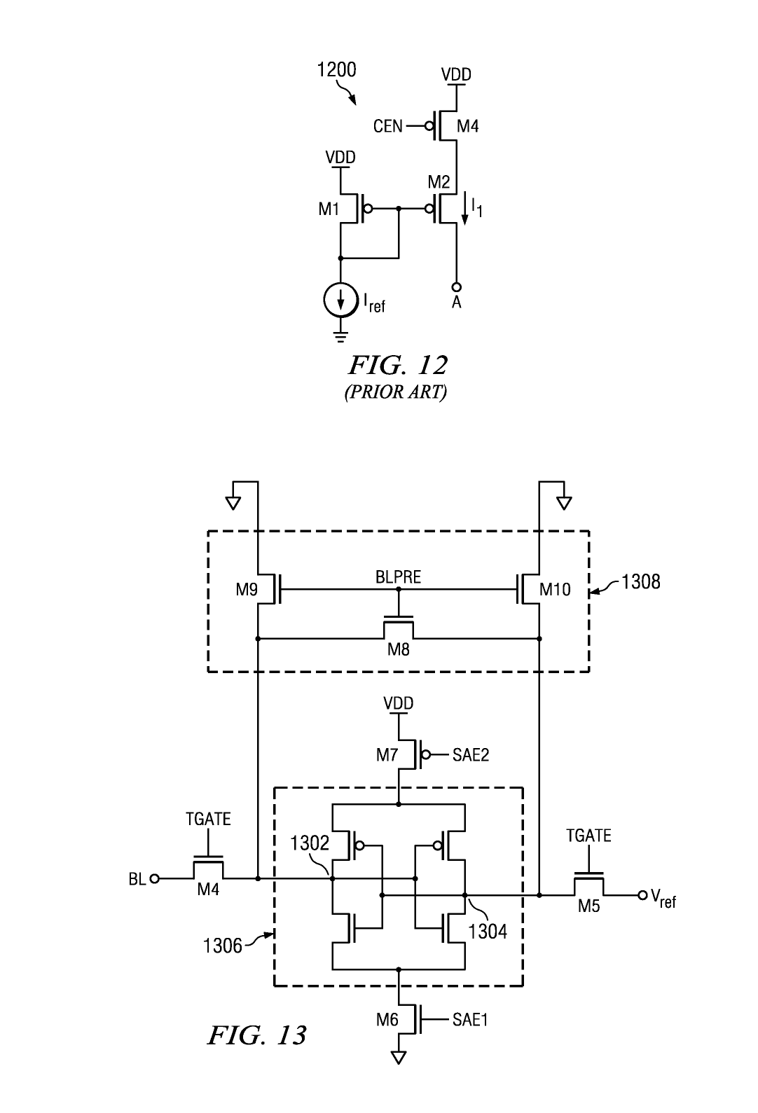

FIG. 12 is an electrical diagram of a current mirror 1200. The current mirror 1200 shown in FIG. 1200 is an example of a constant current source 1102 that may be used to charge the bit line shown in FIG. 11. In this example of a constant current source 1102, the current mirror 1200 includes two PFET (p-type field-effect transistor) transistors, M1, M2 and M4, and a current reference I_{ref}. When transistor M4 is enabled (i.e. CEN is a high logical value), the constant current in current reference I_{ref} is “mirrored” in transistor M2. The timing of signal CEN is controlled by the timing generation circuit 800 shown in FIG. 8.

FIG. 13 is a schematic diagram of a sense amplifier 1110. The schematic 1300 shown in FIG. 13 comprises a cross-coupled latch 1306, two transfer-gate transistors M4 and M5, transistors M6 and M7 that enable the latch 706 and pre-charge circuit 1308. The pre-charge circuit 1308 comprises NMOS transistors M8, M9 and M10 that pre-charge nodes 1302 and 1304 to ground when control signal BLPRE is a logical high value. The signals that control the operation of the sense amplifier are TGATE (transfer gate), SAE1 (sense amp enable), SAE2 (sense amp enable) and BLPRE. The timing of the control signals TGATE, SAE1, SAE2 and BLPRE are controlled by the timing generation circuit 800 shown in FIG. 8.

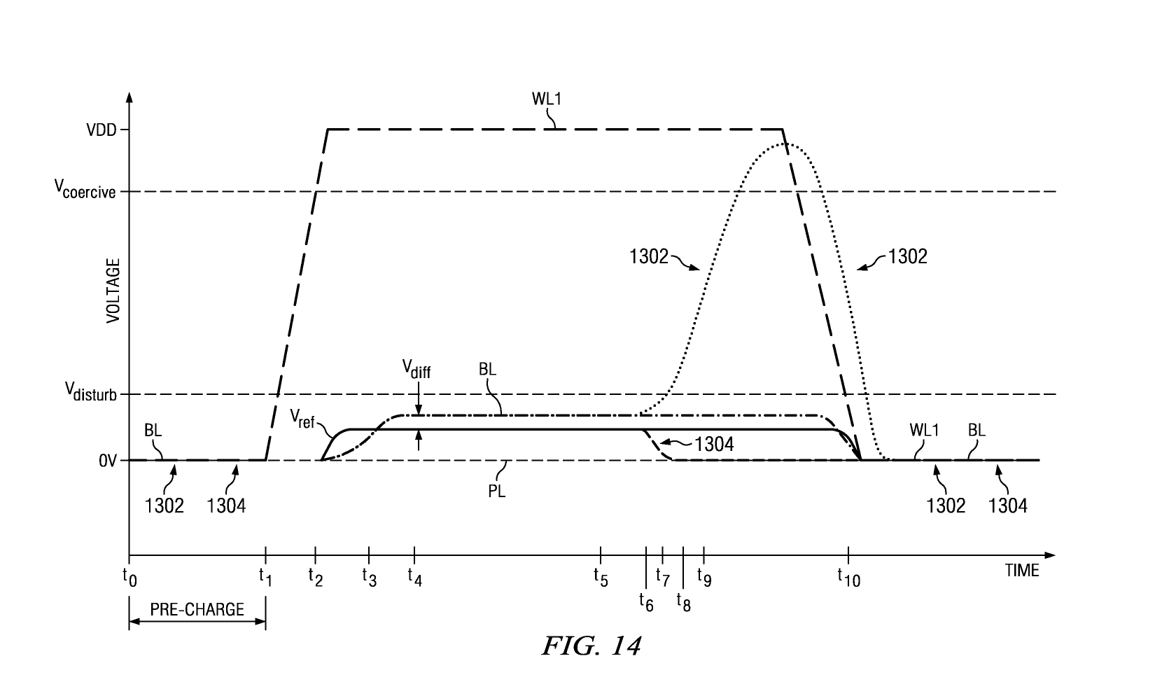

FIG. 14 is a timing diagram illustrating how a 1-T, 1-C ferroelectric memory cell MC1 shown in FIG. 11 is read according to an embodiment of the invention. In this example of the invention, from time t0 to time t1, the bit line BL and nodes 1302 and 1304 in the sense amp 1110 are grounded. The plate lines PL are grounded during the entire reading of the memory cell MC1. At time t2, word line WL1 is driven to a logical high value. In this example the ferroelectric capacitor C1 is charged to a logical one. When the word line WL1 is driven to a logical high value, transistor T3 electrically connects ferroelectric capacitor C3 to bit line BL. As result, the total capacitance seen at port A of the constant current source 1102 is equal to the capacitance of the bit line BL and the ferroelectric capacitor C3.

The charging of bit line BL starts at t2 and reference voltage V_{ref} is applied to the sense amp 1110 as shown in FIG. 14. At time t3, the constant current source 1102 is turned off and bit line BL is no longer charged by the constant current source 1102. The time from t2 to t3 is calculated so as to not allow the voltage V_{bl} on bit line BL to exceed the disturb voltage V_{disturb}. The disturb voltage V_{disturb} is any voltage applied to the ferroelectric capacitor C3 that reduces the polarization on capacitor C3. The coercive voltage V_{coercive} is less than VDD.

From time t4 until time t9, the voltage differential _{Vdiff} between bit line BL and _{Vref} is sensed by the sense amp 1110. The sensing begins by turning on the transfer-gate transistors M4 and M5 shown in FIG. 13. The signal TGATE is applied to the gates of transistors M4 and M5 at time t4. At time t4, the signal TGATE is a logical high signal and the transfer-gate transistors M4 and M5 are turned on. Because the transfer-gate transistors M4 and M5 are turned on, the voltage Vbl1 on bit line BL and the voltage _{Vref} are transferred to nodes 1302 and 1304 respectively. At time t5, the transfer-gate transistors M4 and M5 are turned off, containing the _{Vdiff} between nodes 1302 and 1304.

At time t6, signal SAE1 goes to a logical high value and turns on transistor M6. Turning on transistor M6 connects latch 1306 to ground. At time t7, signal SAE2 transitions from a logical high value to a logical low value turning on transistor M7. When transistor M7 is on, the voltage VDD is applied to the latch 1306. After both ground and VDD are applied to the latch, the latch 706 “flips” and node 1302 is driven to voltage VDD and node 704 is driven to ground. At time t8, the signal SAE1 goes to a logical low level turning off transistor M6. At time t9, the signal SAE2 goes to a logical high level turning off transistor M7 and ending the sensing time of the sense amp 1300. At time t10, the word line WL1, the bit line BL and nodes 1302 and 1304 are grounded.

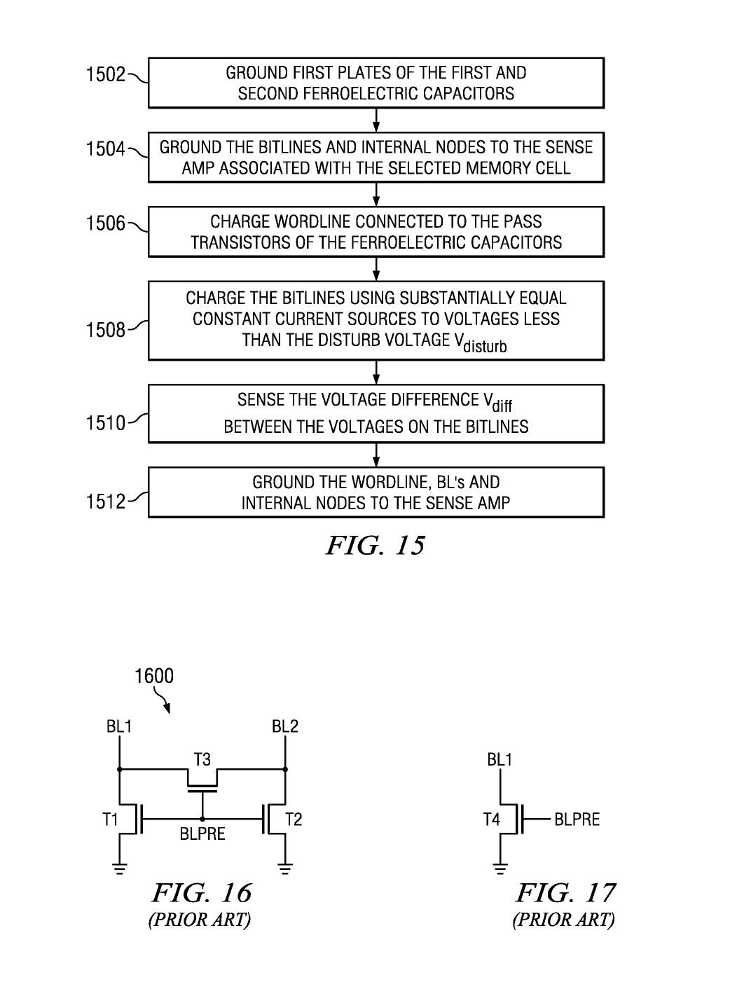

FIG. 15 is a flow chart illustrating how a 2-T, 2-C ferroelectric memory cell is read according to an embodiment of the invention. In this embodiment of the invention, plates on ferroelectric capacitors C1 and C2 are grounded during step 1502. During step 1504 the bit lines BL1 and BL2 (shown in FIG. 5) and internal node 702 and 704 are grounded. During step 1506, the word line WL1 connected to the gates of pass transistors T1 and T2 (shown in FIG. 5) are charged to a logical high value (e.g. VDD). When transistors T1 and T2 are turned on, the capacitance of ferroelectric capacitor C1 is added to the capacitance of the BL1 and the capacitance of ferroelectric capacitor C2 is added to the capacitance of the BL2.

In this example, a logical one is stored on ferroelectric capacitor C1 and a logical zero is stored on ferroelectric capacitor C2. Because a logical zero is stored on ferroelectric capacitor C2 and a logical one is stored on ferroelectric capacitor C1, the capacitance on ferroelectric capacitor C2 is greater the ferroelectric capacitor C2. During step 1508, substantially equal constant current sources begin charging the bit line BL1 plus the ferroelectric capacitor C1 and bit line BL2 plus the ferroelectric capacitor BL2 respectively. Because the current sources are constant and substantially equal and the capacitance of C2 is larger than the capacitance of C1, the voltage on bit line BL1 increases faster than the voltage on BL2.

During step 1510, the sense amp 510 senses the voltage difference V_{diff} between the voltage on bit line BL1 and the voltage on bit line BL2. After the voltage difference V_{diff} is sensed, the word line WL1, bit lines BL1 and BL2, and the internal nodes 702 and 704 are grounded as shown in step 1512.

The foregoing description has been presented for purposes of illustration and description. It is not intended to be exhaustive or to limit the invention to the precise form disclosed, and other modifications and variations may be possible in light of the above teachings. The embodiments were chosen and described in order to best explain the applicable principles and their practical application to thereby enable others skilled in the art to best utilize various embodiments and various modifications as are suited to the particular use contemplated. It is intended that the appended claims be construed to include other alternative embodiments except insofar as limited by the prior art.

What is claimed is:

1. A method of operating a ferroelectric memory to read a stored data state from a selected memory cell without changing the stored data state, the memory cell having a ferroelectric capacitor with first and second plates, and a pass transistor connected between the second plate of the capacitor and a bit line, the ferroelectric capacitor capable of being polarized into first and second data states, the method comprising the steps of:
grounding the first plate of the ferroelectric capacitor;
grounding the bit line associated with the selected memory cell;
charging a word line connected to the gate of the pass transistor to cause conduction between the second plate of the ferroelectric capacitor and the bit line;
charging the bit line to a voltage smaller than the disturb voltage of the ferroelectric capacitor;
sensing a difference in voltage between the voltage on the bit line and a reference voltage; and
grounding the word line and the bit line.

2. The method of claim 1, wherein the bit line is charged using a substantially constant current.

3. The method of claim 2 wherein the bit line is charged at a substantially constant current using a current mirror.

4. The method of claim 1 wherein when a number of consecutive reads of the selected memory cell causes the voltage on the ferroelectric capacitor to come reasonably close to changing the data state on the ferroelectric capacitor, the selected memory cell is written to with a coercive voltage.

5. The method of claim 1, wherein the steps of grounding the first plate, grounding the bit line, charging the word line, charging the bit line, sensing the difference in voltage between the voltage on the bit line and the reference voltage and grounding the word line and bit line are performed for a plurality of memory cells arranged in a selected row of memory cells in the ferroelectric memory.

6. A non-volatile memory, comprising:
a plurality of memory cells arranged in rows and columns, each memory cell comprising:
a capacitor having a first plate coupled to a plate line associated with a row containing the memory cell, having a second plate, and having ferroelectric material disposed between the first and second plates, wherein the capacitor is polarized to a first data state by a positive voltage greater than a first coercive voltage being applied across the first and second plates, and wherein the capacitor is polarized to a second data state by a negative voltage of a magnitude greater than a second coercive voltage being applied across the first and second plates;
a pass transistor having a source/drain path connected between the second plate of the capacitor and a bit line associated with a column containing the memory cell, and having a gate coupled to a word line associated with the row containing the memory cell;
a plurality of sense amplifiers, each coupled to one of a plurality of bit lines and a reference voltage;
a plurality of current sources, each coupled to one of a plurality of bit lines;
write circuitry, coupled to the plurality of bit lines;
word line driver circuitry for applying selected voltages to one or more of a plurality of word lines in each memory access cycle;
plate line driver circuitry, for applying selected voltages to one or more of a plurality of plate lines in each memory access cycle;
wherein during a read cycle, the bit line of memory cells in a selected column are initially grounded;
wherein during the read cycle, the first plate of the ferroelectric capacitor of memory cells in a selected row is grounded by the plate line driver circuitry and the word line driver circuitry applies a word line voltage to the gate of the pass transistor of memory cells in a selected row, the word line voltage sufficient to cause conduction between the second plate of the ferroelectric capacitor and the bit line of memory cells in a selected column;
wherein during the read cycle, the bit line of memory cells in a selected column is charged by a current source in a selected row and column to a voltage less than a disturb voltage;
wherein during the read cycle, a sense amp coupled to the bit line of memory cells in a selected column senses the difference in voltage on the bit line and a reference voltage; and
wherein during the read cycle, the word line of memory cells in a selected row and the bit line of memory cells in a selected column are grounded.

7. The non-volatile memory of claim 6 wherein the bit line of memory cells in a selected column charged by the current source in a selected column is charged at a substantially constant current.

8. The non-volatile memory of claim 7, wherein each constant current source in the plurality of constant current sources comprises a current mirror.

9. The non-volatile memory of claim 6 wherein when a number of consecutive read cycles of the selected memory cells causes the voltage on the ferroelectric capacitor to come reasonably close to changing the data state of the ferroelectric capacitor, the selected memory cells are written to with a coercive voltage.

10. A method of operating a ferroelectric memory to read a stored data state from a selected memory cell without changing the stored data state, the memory cell having a first ferroelectric capacitor, a second ferroelectric capacitor, a first pass transistor and second pass transistor, wherein each ferroelectric capacitor has first and second plates, wherein the first transistor is connected between the second plate of the first ferroelectric capacitor and a first bit line, wherein the second transistor is connected between the second plate of the second ferroelectric capacitor and a second bit line, the first and second ferroelectric capacitors capable of being polarized into first and second data states, the method comprising the steps of:
grounding the first plate of the first ferroelectric capacitor and the first plate of the second ferroelectric capacitor;
grounding the first and second bit lines associated with the selected memory cell;
charging a word line connected to the gates of the first and second pass transistors to cause conduction between the second plate of the first ferroelectric capacitor and the first bit line and the second plate of the second ferroelectric capacitor and the second bit line respectively;
charging the first bit line to a voltage smaller than the disturb voltage of the first ferroelectric capacitor while simultaneously charging the second bit line to a second voltage smaller than the disturb voltage of the second ferroelectric capacitor
sensing the difference in voltage between the voltage on the first bit line and the voltage on the second bit line; and
grounding the word line, the first bit line and the second bit line.

11. The method of claim 9, wherein the first bit line is charged using a first constant current source and the second bit line is charged using a second constant current source, wherein the first and second constant current sources provide approximately the same constant current.

12. The method of claim 11 wherein the first and second constant current sources are provided using current mirrors.

13. The method of claim 10 wherein when a number of consecutive reads of the selected memory cell causes the voltages on either the first or second ferroelectric capacitor to come reasonably close to changing the data state of the first or second ferroelectric capacitor, the selected memory cell is written to with a coercive voltage.

14. The method of claim 10, wherein the steps of grounding the first plates of the first and second ferroelectric capacitors, grounding the bit lines, charging the word line, charging the bit lines, sensing the difference in voltage between the voltage on the first bit line and the voltage on the second bit line and grounding the word line and bit lines are performed for a plurality of memory cells arranged in a selected row of memory cells in the ferroelectric memory.

15. A non-volatile memory, comprising:
a plurality of memory cells arranged in rows and columns, each memory cell comprising:
a first capacitor having a first plate coupled to a plate line associated with a row containing the memory cell, having a second plate, and having ferroelectric material disposed between the first and second plates, wherein the first capacitor is polarized to a first data state by a positive voltage greater than a first coercive voltage being applied across the first and second plates, and wherein the first capacitor is polarized to a second data state by a negative voltage of a magnitude greater than a second coercive voltage being applied across the first and second plates;
a first pass transistor having a source/drain path connected between the second plate of the first capacitor and a first bit line associated with a column containing the memory cell, and having a gate coupled to a word line associated with the row containing the memory cell;
a second capacitor having a first plate coupled to the plate line associated with the row containing the memory cell, having a second plate, and having ferroelectric material disposed between the first and second plates, wherein the second capacitor is polarized to a first data state by a positive voltage greater than a first coercive voltage being applied across the first and second plates, and wherein the second capacitor is polarized to a second data state by a negative voltage of a magnitude greater than a second coercive voltage being applied across the first and second plates;
a second pass transistor having a source/drain path connected between the second plate of the second capacitor and a second bit line associated with the column containing the memory cell, and having a gate coupled to the word line associated with the row containing the memory cell;
a plurality of sense amplifiers, each coupled to one of a plurality of first and second bit lines;
a plurality of current sources, each coupled to one of a plurality of first and second bit lines;
write circuitry, coupled to the plurality of first and second bit lines;
word line driver circuitry for applying selected voltages to one or more of a plurality of word lines in each memory access cycle;
plate line driver circuitry, for applying selected voltages to one or more of a plurality of plate lines in each memory access cycle;
wherein during a read cycle, the first and second bit lines of memory cells in a selected column are initially grounded;
wherein during the read cycle, the first plate of the first and second ferroelectric capacitors of memory cells in a selected row is grounded by the plate line driver circuitry and the word line driver circuitry applies a word line voltage to the gates of the first and second pass transistors of memory cells in a selected row, the word line voltage sufficient to cause conduction between the second plate of the first and second ferroelectric capacitors and the first and second bit lines respectively of memory cells in a selected row;
wherein during the read cycle, the first and second bit lines of memory cells in a selected row and column are charged by first and second current sources respectively in a selected row and column to voltages less than a disturb voltage;
wherein during the read cycle, a sense amp coupled to the first and second bit lines of memory cells in a selected row and column senses the difference in voltage on the first bit line and the second bit line; and
wherein during the read cycle, the word line of memory cells in a selected row and the bit line of memory cells in a selected column are grounded.

16. The non-volatile memory of claim 15 wherein the first and second bit lines of memory cells in a selected row and column are charged by a first current source and a second current source respectively; the first and second current sources having substantially the same constant current.

17. The non-volatile memory of claim 16, wherein the first and second constant current sources comprise current mirrors.

18. The non-volatile memory of claim 15 wherein when a number of consecutive read cycles of the selected memory cells causes the voltage on the either the first or second ferroelectric capacitor to come reasonably close to changing the data state of either the first or second ferroelectric capacitor, the selected memory cells are written to with a coercive voltage.
